(19) United States
(12) Patent Application Publication
(10) Pub. No.: US 2022/0325409 A1
(43) Pub. Date: Oct. 13, 2022

(54) DEPOSITION OF BETA-GALLIUM OXIDE THIN FILMS

(71) Applicant: Elham RAFIE BORUJENY, Edmonton (CA)

(72) Inventor: Elham RAFIE BORUJENY, Edmonton (CA)

(21) Appl. No.: 17/708,932

(22) Filed: Mar. 30, 2022

Related U.S. Application Data
(60) Provisional application No. 63/173,260, filed on Apr. 9, 2021.

(51) Int. Cl. C23C 16/455; C23C 16/40

(52) U.S. Cl. CPC C23C 16/45527; C23C 16/40

(57) ABSTRACT

An epitaxial deposition process, such as atomic layer deposition, is provided for forming a thin film comprising beta-gallium oxide (β-Ga₂O₃) on a substrate, such as sapphire. The process involves depositing a buffer layer of metastable Ga₂O₃, such as α-Ga₂O₃, on the substrate, and then reacting a gallium precursor, such as TEG, with an oxygen precursor, such as oxygen plasma, to deposit a layer comprising β-Ga₂O₃ on the buffer layer. The Ga₂O₃ film formed by the process may comprise highly oriented crystalline β-Ga₂O₃, with negligible amounts of other Ga₂O₃ polymorphs.

### CROSS-REFERENCE TO RELATED APPLICATION

This application claims priority to U.S. Provisional Patent Application No. 63/173,260, filed on Apr. 9, 2021, the entire disclosure of which is incorporated by reference herein in its entirety for all purposes.

### FIELD OF THE INVENTION

The present invention relates to forming semiconductor thin films, using epitaxial deposition processes.

### BACKGROUND OF THE INVENTION

Power electronic devices are devices that convert DC power to AC power, or vice versa. For example, power electronic devices convert DC power generated by solar cells and fuel cells to AC power, thereby making it usable by consumers. As another example, power electronic devices convert AC power supplied by a provider to DC power, thereby making it usable for charging the battery of an electric car or a portable electronic device.

Research into new materials for power electronic devices has emerged as an inseparable part of sustainable development and efficient handling of electrical energy during the past three decades. Wide bandgap semiconductors such as GaN and SiC have been considered as candidate materials for power devices to overcome the limitations of their traditional predecessors (such as Si and GaAs) in meeting the growing needs and the stringent requirements of the high energy demand society today.

During the past few years, gallium oxide (Ga₂O₃) has been proposed as an alternative material for such semiconductor devices promising to offer higher efficiency in power handling than the materials in use today and expected to compete with and complement the outstanding properties of GaN as the frontrunner material for power electronic devices [References no. 1-5]. In addition to power applications, Ga₂O₃ expands the wavelength span of optoelectronic devices to the deep UV [Reference no. 3]. The properties of Ga₂O₃ depend on its crystal structure [Reference no. 3], and high quality films of crystalline forms of Ga₂O₃, specifically of its most stable polymorph, are required for fabricating devices.

Therefore, most attention has been devoted to monoclinic β-Ga₂O₃ as the most stable polymorph of Ga₂O₃ (belonging to the space group C2/m). With the recent availability of β-Ga₂O₃ bulk wafers (grown from the melt at high temperatures, ca. 1800° C.) [References no. 1, 3-5], homoepitaxial thin films of this Ga₂O₃ polymorph can be deposited on its native substrate [References no. 1, 3, 4]. However, growing high quality β-Ga₂O₃ films on the native substrate (i.e., homoepitaxy) is currently performed at high temperatures, ca. 600-800° C., which consumes a lot of energy, and still only produces β-Ga₂O₃ films on β-Ga₂O₃ wafers that only allow for fabrication of very limited devices for limited applications [References no. 1, 2]. In addition, bulk β-Ga₂O₃ wafers have a low thermal conductivity which hinders the ability of β-Ga₂O₃ devices to operate at their expected capabilities [Reference no. 6]. Meanwhile, growing β-Ga₂O₃ films on non-native substrates (i.e., heteroepitaxy) is even more challenging; it is only possible on very limited substrates (e.g., mainly sapphire) [References no. 3, 6-8], while having to carefully choose very specific process conditions based on each process and the instrument being used [Reference no. 8]. Otherwise, post-growth annealing at high temperatures (>500° C.) will be required to achieve a high quality film [Reference no. 7].

In addition to β-Ga₂O₃, which is the most stable polymorph of Ga₂O₃, gallium oxide has a few other polymorphs that are metastable; these include γ-, ε-, κ-, δ-, and α-Ga₂O₃ [References no. 3, 9-14]. Currently, the γ polymorphs can only be obtained in specific process conditions; meanwhile, information about the ε, κ, and δ polymorphs is limited and, in some cases, debated in the literature [References no. 11, 12] mainly because these polymorphs are difficult to obtain as isolated phases which makes their structure determination challenging [Reference no. 7]. On the other hand, the α-Ga₂O₃ metastable polymorph is the most studied and technologically appealing metastable polymorph due to its superior properties for both power handling and optoelectronics and its stability at ambient to high temperatures and pressures [References no. 3, 7, 9, 10].

There remains a need in the art for methods for forming a high quality, thin film comprising β-Ga₂O₃ on a non-native substrate, using an energy-efficient fabrication process.

### SUMMARY OF THE INVENTION

The present invention involves using an epitaxial deposition process, such as plasma-enhanced atomic layer deposition, to form an intermediate buffer layer of a metastable Ga₂O₃, such as α-Ga₂O₃, before depositing reactants that form the β-Ga₂O₃ film on the buffer layer. In embodiments, the process may be optimized to achieve crystallinity at a temperature of about 277° C. which is relatively low in the context of crystalline material growth. In embodiments, the process provides an energy-efficient fabrication process for growing β-Ga₂O₃ films, with minimal inclusion of other Ga₂O₃ polymorphs, on non-native substrates on which an intermediate layer of metastable Ga₂O₃ can be grown.

In one aspect, the present invention comprises a method for forming a thin film comprising beta-gallium oxide (β-Ga₂O₃) on a substrate. The method uses an epitaxial deposition process comprising the steps of:
(a) depositing a buffer layer of metastable Ga₂O₃ on the substrate; and
(b) reacting a gallium precursor with an oxygen precursor to deposit a layer comprising β-Ga₂O₃ on the buffer layer.

In embodiments of the method, the method further comprises repeating step (b) to deposit one or more additional layers comprising β-Ga₂O₃ on a previously deposited layer comprising β-Ga₂O₃.

In embodiments of the method, the layer comprising β-Ga₂O₃ comprises at least 90% β-Ga₂O₃, by ratio of mass of β-Ga₂O₃ to mass of α-Ga₂O₃ and β-Ga₂O₃, collectively.

In embodiments of the method, the epitaxial deposition process is an atomic layer deposition (ALD) process.

In embodiments of the method, the buffer layer is a single monolayer of metastable Ga₂O₃. In embodiments of the method, the layer comprising β-Ga₂O₃ is a single monolayer comprising β-Ga₂O₃.

In embodiments of the method, the gallium precursor comprises triethylgallium (TEG) gas. In embodiments of the method, the oxygen precursor comprises an oxygen plasma.

In embodiments of the method, step (b) comprises the sub-steps of:
(i) providing a 0.1 s pulsed dose of the gallium precursor comprising triethylgallium (TEG) into a reaction chamber containing the substrate; and
(ii) providing a 10 s pulsed dose of the oxygen precursor comprising oxygen plasma into the reaction chamber.

In embodiments of the method, the metastable gallium oxide comprises α-Ga₂O₃. In embodiments of the method, step (a) comprises the sub-steps of:
(i) depositing a layer of wurtzite gallium nitride (w-GaN) on the substrate; and
(ii) reacting the layer of w-GaN with an oxygen precursor to deposit the buffer layer comprising α-Ga₂O₃ on the substrate.

In the foregoing embodiments of the method, sub-step (i) of depositing a layer of wurtzite gallium nitride (w-GaN) on the substrate comprises the sub-steps of:
(1) depositing a layer of gallium precursor on the substrate; and
(2) reacting the layer of gallium precursor with a nitrogen precursor to deposit the layer of w-GaN on the substrate.

The gallium precursor used in sub-step (1) may comprise triethylgallium (TEG) gas. The nitrogen precursor used in sub-step (2) may comprise N₂/H₂ forming gas plasma. In such embodiments of the method, the oxygen precursor used in sub-step (ii) of reacting the layer of w-GaN with an oxygen precursor to deposit the buffer layer comprising α-Ga₂O₃ on the substrate comprises oxygen plasma. In one embodiment of the method: sub-step (1) may comprise providing a 0.1 s pulsed dose of the gallium precursor comprising triethylgallium (TEG) into a reaction chamber containing the substrate; sub-step (2) may comprise providing a 15 s pulsed dose of the nitrogen precursor comprising N₂/H₂ forming gas plasma into the reaction chamber; and sub-step (ii) of reacting the layer of w-GaN with an oxygen precursor to deposit the buffer layer comprising α-Ga₂O₃ on the substrate comprises providing a 1.5 s pulsed dose of the oxygen precursor comprising oxygen plasma into the reaction chamber.

In embodiments of the method, the substrate is a non-native substrate, which may comprise a sapphire, and more particularly, c-plane sapphire.

In another aspect, the present invention comprises a thin film comprising beta-gallium oxide (β-Ga₂O₃) formed on a non-native substrate by any embodiment of the method described above. In embodiments, the thin film comprises at least 90% β-Ga₂O₃, by ratio of mass of β-Ga₂O₃ to mass of α-Ga₂O₃ and β-Ga₂O₃, collectively.

### BRIEF DESCRIPTION OF THE DRAWINGS

In the drawings, like elements may be assigned like reference numerals. The drawings are not necessarily to scale, with the emphasis instead placed upon the principles of the present invention. Additionally, each of the embodiments depicted are but one of a number of possible arrangements utilizing the fundamental concepts of the present invention.

FIG. 1 is a schematic depiction of an embodiment of a “buffer-mediated Ga₂O₃” deposition process of the present invention for forming a thin film comprising gallium oxide (β-Ga₂O₃) on a substrate.

FIG. 2 is a schematic depiction of an embodiment of a GaN-mediated Ga₂O₃ deposition process used in a step of the embodiment of the method of the present invention to form a buffer layer comprising α-Ga₂O₃.

FIG. 3 is a schematic depiction of an embodiment of a GaN-mediated Ga₂O₃ deposition process for forming a buffer layer comprising α-Ga₂O₃ on a sapphire substrate, an out-of-plane coupled XRD pattern for an embodiment of the resulting buffer layer, and the XRD pattern of the bare sapphire substrate to better distinguish thin film peaks in the pattern.

FIG. 4 is an atomic resolution scanning transmission electron microscope (STEM) image for the embodiment of a buffer layer and sapphire substrate studied in FIG. 3. The image is obtained with a high-angle annular dark-field imaging (HAADF) detector highlighting the atomic columns by using a combination of high-pass and radial Wiener filters.

FIG. 5 is a nano-beam electron diffraction pattern of focused regions of the embodiment of the buffer layer studied in FIG. 3.

FIG. 6 is a nano-beam electron diffraction pattern of focused regions of the embodiment of the sapphire substrate studied in FIG. 3.

FIG. 7 is a schematic depiction of an embodiment of a “conventional Ga₂O₃ deposition process” in the prior art for forming a Ga₂O₃ layer on a sapphire substrate, an out-of-plane coupled XRD pattern for the resulting Ga₂O₃ layer, and the XRD pattern of the bare sapphire substrate to better distinguish thin film peaks in the pattern.

FIG. 8 is a schematic depiction of an embodiment of a “buffer-mediated Ga₂O₃ deposition process” of the present invention for forming a thin film comprising gallium oxide (β-Ga₂O₃) on a sapphire substrate, an out-of-plane coupled XRD pattern for the resulting Ga₂O₃ layer deposited on a sapphire substrate, and the XRD pattern of the bare sapphire substrate to better distinguish thin film peaks in the pattern.

FIG. 9 is a chart showing optical constants of the embodiment of the β-Ga₂O₃ film studied in FIG. 8, in comparison with the buffer layer studied in FIG. 3, and the Ga₂O₃ layer studied in FIG. 7, as produced after an equal number of TEG doses. The values of bandgap and refractive index at a photon energy of 1.96 eV (corresponding to the wavelength of 632.8 nm) are listed for comparison.

FIG. 10 is a table of non-limiting examples of gallium precursors that may be used in the method of the present invention.

FIG. 11 is a table of non-limiting examples of oxygen precursors that may be used in the method of the present invention.

### DETAILED DESCRIPTION OF EMBODIMENTS OF THE INVENTION

### Definitions

The invention relates to formation of semiconductor thin films using an epitaxial deposition process. Any term or expression not expressly defined herein shall have its commonly accepted definition understood by a person skilled in the art. As used herein, the following terms have the following meanings.

“Atomic layer deposition” or “ALD” is a subclass of chemical vapor deposition, used to deposit thin films onto a substrate. ALD typically involves the sequential use of gas phase reactants, and/or plasma phase reactants, and surface chemical processes.

“Buffer layer” is one or more material layer(s) that provide an interface between a substrate underlying the buffer layer and an overlying film formed on the buffer layer.

“Epitaxial deposition process”, as used herein, refers to a process that involves placing a substrate in a reaction chamber, and introducing one or more precursor (reactant) materials into the reaction chamber, such that the precursor(s) or their reaction product(s), deposit on the substrate to form a non-amorphous, crystalline layer having defined crystallographic orientation(s) relative to the underlying layer(s). In non-limiting embodiments, the epitaxial deposition process may comprise chemical vapor deposition (CVD) processes, physical vapor deposition (PVD) processes, or any other suitable deposition techniques as are known to a person skilled in the art of forming thin films. Chemical vapor deposition (CVD) processes may be performed using a variety of techniques known to a person skilled in the art, with non-limiting embodiments including metal-organic CVD (MOCVD), mist CVD, low pressure CVD, atmospheric CVD, plasma-assisted CVD (also referred to as plasma-enhanced CVD), photo-assisted CVD, molecular layer deposition (MLD), and atomic layer deposition (ALD) including spatial ALD, thermal ALD, plasma-assisted ALD (also referred to as plasma-enhanced ALD), and photo-assisted ALD. Metal-organic vapor phase epitaxy (MOVPE), halide vapor phase epitaxy (HVPE) and liquid phase epitaxy (LPE) may also be used. Physical vapor deposition (PVD) processes may be performed using a variety of sputtering techniques known to a person skilled in the art, with non-limiting embodiments including ion beam deposition, reactive sputtering, magnetron sputtering, and RF diode sputtering. Physical vapor deposition (PVD) processes may also be performed using a variety of evaporation techniques known to a person skilled in the art, with non-limiting embodiments including thermal evaporation, e-beam evaporation, pulsed laser deposition (PLD), and molecular beam epitaxy (MBE) including reactive MBE.

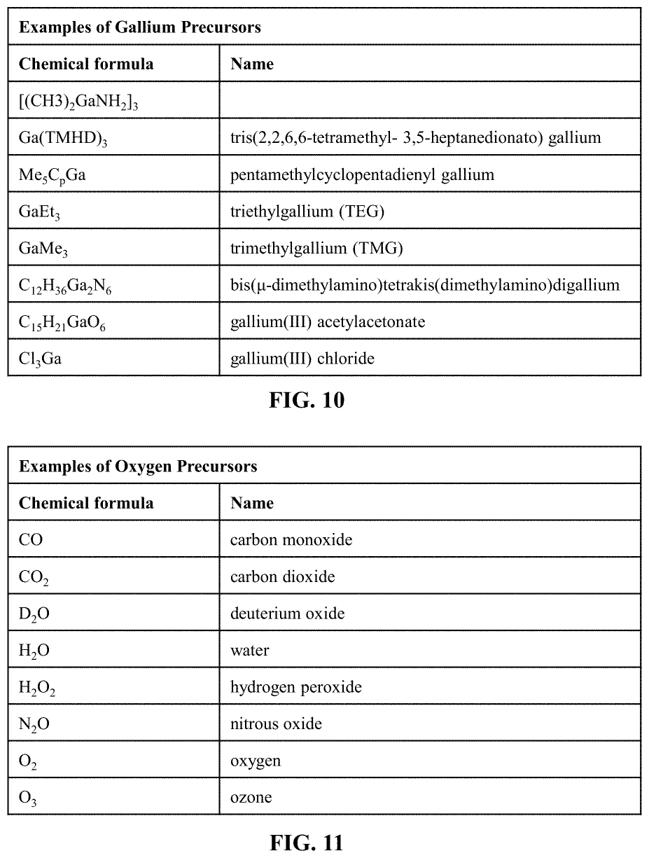

“Gallium precursor”, as used herein, refers to a substance comprising gallium atoms, which is suitable for use as reactant in an epitaxial deposition process. In non-limiting embodiments, including embodiments where the epitaxial deposition process is an atomic layer deposition process, the gallium precursor may comprise one or a combination of the substances shown in the table of FIG. 10.

“Metastable gallium oxide” or “metastable Ga₂O₃”, as used herein, refers to any one of α-Ga₂O₃, γ-Ga₂O₃, ε-Ga₂O₃, κ-Ga₂O₃, and δ-Ga₂O₃ polymorphs.

“Monolayer”, as used herein, refers to a single layer of atoms, or molecules.

“Nitrogen precursor”, as used herein, refers to a substance comprising nitrogen atoms, which is suitable for use as a reactant in an epitaxial deposition process. In non-limiting embodiments, including embodiments where the epitaxial deposition process is an atomic layer deposition process, the nitrogen precursor may comprise one or a combination of nitrogen (N₂) gas or plasma, ammonia (NH₃) gas or plasma, or a N₂/H₂ forming gas or plasma.

“N₂/H₂ forming gas plasma”, as used herein, refers to a plasma formed from a mixture of nitrogen gas (N₂) and hydrogen gas (H₂). In non-limiting embodiments, the N₂/H₂ forming gas plasma is formed from a mixture of 95% N₂ gas and 5% H₂ gas, by volume. In other embodiments, the N₂/H₂ forming gas plasma may be formed from a mixture of N₂ gas and H₂ gas having a different volumetric ratio of N₂ gas and H₂ gas. It is within the skill of a person skilled in the art of thin film deposition to select a suitable volumetric ratio of N₂ gas and H₂ gas to react with a gallium precursor to form w-GaN. Usually, the amount of H₂ gas is selected to be less than about 5.7% by volume to avoid the risk of spontaneous or hazardous combustion of H₂ gas.

“Oxygen precursor”, as used herein, refers to a substance comprising oxygen atoms, which is suitable for use as reactant in an epitaxial deposition process. In non-limiting embodiments, including embodiments where the epitaxial deposition process is an atomic layer deposition process, the oxygen precursor may comprise one or a combination of the substances shown in the table of FIG. 11.

“Substrate”, as used herein, refers to a material layer (e.g., a wafer, a membrane, a multilayer, or a laminated structure) on which overlying layers of material may be deposited using an epitaxial deposition process. “Non-native substrate”, as used herein refers to a substrate comprising a material other than β-Ga₂O₃. In embodiments, the non-native substrate may be a gallium nitride-compatible (GaN-compatible) substrate comprising sapphire, Si, SiC, or diamond, or any other suitable substrate known in the art.

### Method of the Present Invention

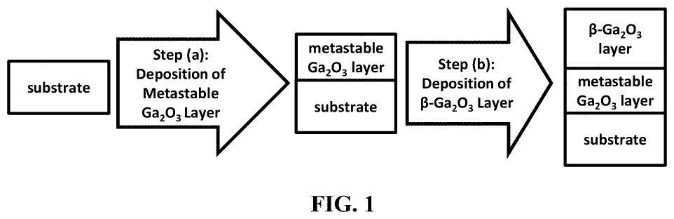

FIG. 1 is a schematic depiction of steps in an embodiment of the method of present invention for forming a thin film comprising β-Ga₂O₃. This method is referred to herein as the “buffer-mediated Ga₂O₃ deposition process”. In one embodiment, the buffer-mediated Ga₂O₃ deposition process uses an epitaxial deposition process comprising the following steps:
(a) depositing a buffer layer of metastable Ga₂O₃ on a substrate;
(b) reacting a gallium precursor (e.g., triethylgallium (TEG) gas) with an oxygen precursor (e.g., oxygen plasma) to deposit a layer of β-Ga₂O₃ on the buffer layer; and
(c) repeating step (b) to deposit additional layers of β-Ga₂O₃ on previously deposited layers of β-Ga₂O₃.

In one non-limiting embodiment, the substrate is a GaN-compatible substrate. In one embodiment, the GaN-compatible substrate is sapphire, and more particularly c-plane sapphire. Abundant data is available for depositing Ga₂O₃ and relevant materials on sapphire [References no. 7, 15, 17, 18].

Step (a): Depositing Buffer Layer of Metastable Ga₂O₃.

In general, step (a) may be performed by any epitaxial deposition process that can produce metastable Ga₂O₃ on the substrate. In embodiments, the metastable Ga₂O₃ may be any one of the α-Ga₂O₃, γ-Ga₂O₃, ε-Ga₂O₃, κ-Ga₂O₃, and δ-Ga₂O₃ polymorphs. For example, in embodiments where the metastable Ga₂O₃ is α-Ga₂O₃, epitaxial deposition processes for forming α-Ga₂O₃ on a substrate known in the art may be suitably used in the present invention. As non-limiting examples, atomic layer deposition (ALD) may be used, and References no. 3 and 6 disclose a variety of techniques, such as mist-CVD, halide vapor phase epitaxy (HVPE), metalorganic vapor phase epitaxy (MOVPE), and molecular beam epitaxy (MBE), among other epitaxial deposition techniques that may be used to grow α-Ga₂O₃.

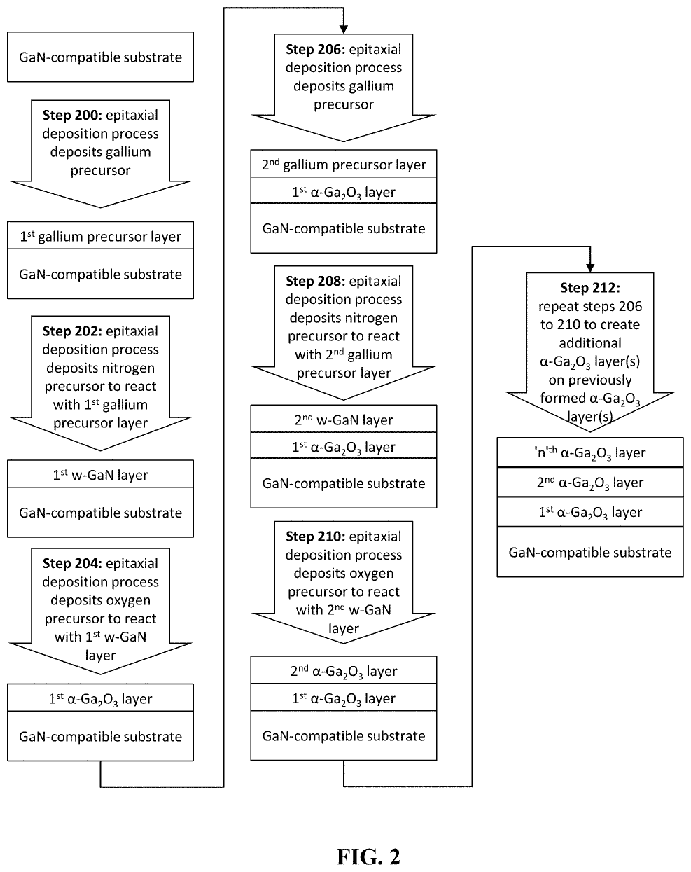

In one non-limiting embodiment as shown in FIG. 2, step (a) is performed by a process referred to herein as the “GaN-mediated α-Ga₂O₃ deposition process”, which uses an epitaxial deposition process comprising the following steps:
(a) depositing a layer of wurtzite gallium nitride (w-GaN) on the substrate (e.g., a non-native substrate, such as sapphire, and more particularly, c-plane sapphire), which may comprise:
   (i) depositing a layer of gallium precursor (e.g., triethylgallium (TEG) gas) on the substrate (step 200); and
   (ii) reacting the layer of gallium precursor with a nitrogen precursor (e.g., N₂/H₂ forming gas plasma) to deposit the layer of w-GaN on the substrate (step 202); and
(b) reacting the layer of w-GaN with an oxygen precursor (e.g., an oxygen plasma) to deposit a layer of α-Ga₂O₃ on the substrate (step 204); and
(c) repeating the foregoing steps (a) and (b) (see steps 206 to 210, and 212) to deposit additional layers of α-Ga₂O₃ on previously deposited layer(s) of α-Ga₂O₃.

In embodiments of the GaN-mediated α-Ga₂O₃ deposition process, the epitaxial deposition process is plasma-enhanced ALD.

In embodiments of the GaN-mediated α-Ga₂O₃ deposition process, each deposited layer of w-GaN, gallium precursor, and nitrogen precursor, and α-Ga₂O₃ is a monolayer.

In embodiments of the GaN-mediated α-Ga₂O₃ deposition process, the process may be performed at a deposition temperature less than about 500° C., and preferably less than about 300° C., such as 277° C.

In embodiments of the GaN-mediated α-Ga₂O₃ deposition process, step (a) is preceded by pretreating the substrate with N₂/H₂ forming gas plasma to remove contamination and pretreat the surface prior to deposition.

In embodiments of the GaN-mediated α-Ga₂O₃ deposition process, sub-steps (a)(i) and (a)(ii) and step (b) may comprise providing pulsed doses of the gallium precursor, nitrogen precursor and oxygen precursor, respectively, into the reaction chamber in which the epitaxial deposition process is performed.

In embodiments of the GaN-mediated α-Ga₂O₃ deposition process, introduction of the gallium precursor and the nitrogen precursor into the reaction chamber is sequential, and the nitrogen precursor reacts with the first gallium precursor layer on the surface of the substrate. In other embodiments (e.g., using chemical vapor deposition), the introduction of the gallium precursor and the nitrogen precursor into the reaction chamber may be simultaneous to form the first layer of w-GaN on the substrate. In either case, the formed layer of w-GaN provides a highly symmetric atomic scale scaffold of gallium atoms, but is sacrificed in the following step to form the layer of α-Ga₂O₃ on the substrate.

In embodiments of the GaN-mediated α-Ga₂O₃ deposition process, any one of sub-steps (a)(i) or (a)(ii) or step (b) may be followed by purging the reaction chamber in which the epitaxial deposition process is performed with an inert gas (e.g., argon gas) to remove any excess of the gallium precursor, nitrogen precursor, or oxygen precursor (as the case may be) and/or reaction byproducts from the reaction chamber.

As demonstrated by the experiment example described below, the GaN-mediated α-Ga₂O₃ deposition process is advantageous because it can be performed using GaN-compatible substrates, and is able to produce a very high quality, highly oriented, metastable α-Ga₂O₃ buffer layer.

Step (b): Depositing β-Ga₂O₃ Layer on Buffer Layer.

In general, step (b) may be performed by any epitaxial deposition process that involves reacting a gallium precursor with an oxygen precursor to deposit a layer of Ga₂O₃ on the buffer layer. This process is referred to herein as the “Ga₂O₃ deposition process”.

In one non-limiting embodiment as shown in part of FIG. 8, the Ga₂O₃ deposition process uses an epitaxial deposition process comprising the following steps:
(a) depositing a layer of triethylgallium (TEG) gas on the buffer layer;
(b) reacting the layer of TEG with oxygen plasma to deposit a layer of Ga₂O₃ on the buffer layer; and
(c) repeating the foregoing steps (a) and (b) to create additional layers of Ga₂O₃ on previously deposited layer(s) of Ga₂O₃.

In embodiments of the Ga₂O₃ deposition process, epitaxial deposition process is plasma-enhanced ALD.

In embodiments of the Ga₂O₃ deposition process, each deposited layer of TEG, oxygen plasma, and Ga₂O₃ is a monolayer.

In embodiments of the Ga₂O₃ deposition process, the process may be performed at a deposition temperature less than about 500° C., and preferably less than about 300° C., such as 277° C.

In embodiments of the Ga₂O₃ deposition process, step (a) may be preceded by pretreating the substrate with oxygen plasma to remove contamination and pretreat the surface prior to deposition.

In embodiments of the Ga₂O₃ deposition process, steps (a) and (b) comprise providing pulsed doses of TEG and the oxygen plasma, respectively, into the reaction chamber in which the epitaxial deposition process is performed.

In embodiments of the Ga₂O₃ deposition process, any one of steps (a) or (b) may be followed by purging the reaction chamber in which the epitaxial deposition process is performed with an inert gas (e.g., argon gas) to remove any excess of the TEG, or oxygen plasma, and/or reaction byproducts from the reaction chamber.

### EXPERIMENTAL EXAMPLES

In the following experimental examples, epitaxial deposition processes by atomic layer deposition were performed at 277° C. on single-side polished (Rₐ<0.3 nm) prime quality c-plane sapphire wafers (see Reference no. 7 for detailed specifications of the wafers) by using a Kurt J. Lesker ALD 150-LX™ system equipped with a remote inductively coupled plasma (ICP) source and a load lock. The error in determining the actual deposition temperatures was ±3° C. The pressure of the reactor was ˜1.1 Torr with ˜1000 sccm continuous flow of argon. In addition, 60 sccm oxygen or N₂/H₂ forming gas was introduced to the reactor during plasma exposures with ˜600 W forward power. This setup is explained in detail elsewhere [Reference no. 7, 19].

Triethylgallium, TEG, (Strem Chemicals, Inc.) was electronic grade (99.9999% Ga) in a stainless steel Swagelok™ cylinder assembly which was not heated during the depositions. All other gases (argon, oxygen, and N₂/H₂ forming gas) were of ultrahigh purity (99.999%, Praxair Canada, Inc.). Substrates were exposed to 60 s plasma to remove contamination and pretreat the surface prior to deposition.

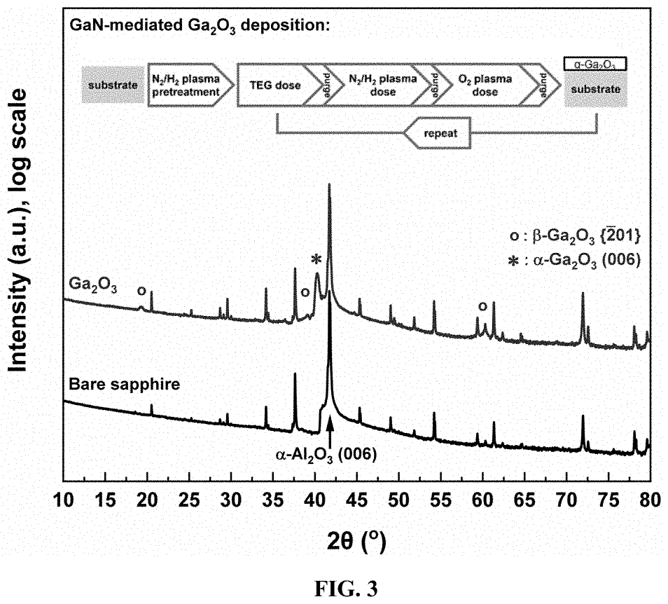

The GaN-mediated α-Ga₂O₃ deposition process, as shown schematically in FIG. 3, was performed by using a recipe consisting of a sequence of 0.1 s TEG dose, 6 s argon purge, 15 s N₂/H₂ forming gas plasma dose, 13 s argon purge, 1.5 s oxygen plasma dose, and 10 s argon purge. (Particulars of this deposition approach are explained in detail in Reference no. 15.) The first four steps (TEG dose, argon purge, N₂/H₂ forming gas plasma dose, and argon purge) implemented with an ALD technique, result in a coherent monolayer of w-GaN through which Ga atoms form a stable and highly symmetric atomic scale, hexagonal scaffold (i.e., possessing 6-fold symmetry). The scaffold steers the oxygen atoms into forming the crystal structure of α-Ga₂O₃ upon oxygen plasma exposure in the remaining two steps (oxygen plasma dose, and final argon purge) of the sequence.

The Ga₂O₃ deposition process was performed by using a recipe consisting of a sequence of 0.1 s TEG dose, 20 s argon purge, 10 s oxygen plasma dose, and 12 s argon purge. (Reducing the two purge times down to 3 s and 2 s, respectively, did not change the deposition results for the conventional Ga₂O₃ deposition process described below.)

The Ga₂O₃ deposition process was performed in two different processes.

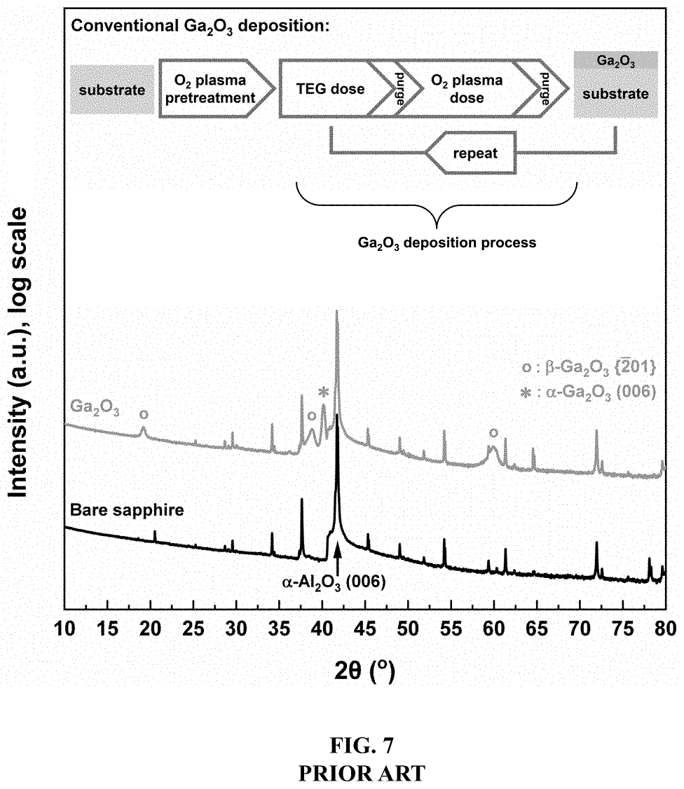

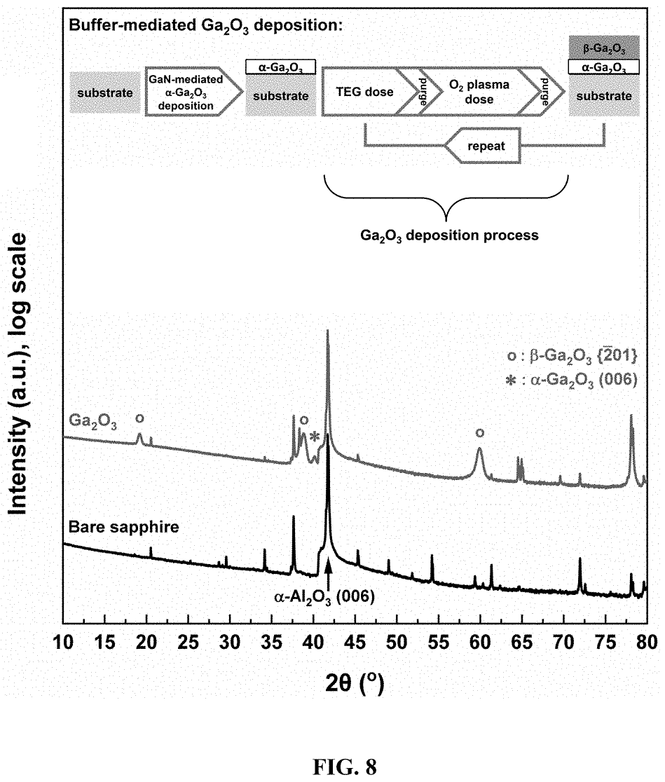

In the first process, as shown schematically in FIG. 7, the Ga₂O₃ deposition process was performed to deposit Ga₂O₃ directly on the substrate—that is, without the buffer layer of metastable Ga₂O₃. This is referred to herein as the “conventional Ga₂O₃ deposition process”, and is further described in Reference no. 7.

In the second process, as shown schematically in FIG. 8, the Ga₂O₃ deposition process was performed to deposit Ga₂O₃ directly on the buffer layer of metastable Ga₂O₃ resulting from the GaN-mediated α-Ga₂O₃ deposition process described above, in accordance with the buffer-mediated Ga₂O₃ deposition process of the present invention.

Ellipsometry measurements were performed on the thin films to measure their thickness and optical properties (including extinction coefficient (k) values, refractive index (n) values, and bandgap). Ellipsometry measurements were done by using a J. A. Woollam M-2000DI™ spectroscopic ellipsometer, permanently mounted on the reactor at an incident angle of 70°, in the spectral range of 0.73-6.40 eV (equivalent to 190-1700 nm) at intervals less than 0.05 eV. Ellipsometry data analysis was done by using CompleteEASE™ software. Thickness and optical constants of the films were obtained based on Tauc-Lorentz modelling of the ellipsometry data (see Reference no. 7 for detailed explanation of the modelling procedure).

In the GaN-mediated α-Ga₂O₃ deposition process (FIG. 3), the conventional Ga₂O₃ deposition process (FIG. 7), and the buffer-mediated Ga₂O₃ deposition process (FIG. 8), optical properties and thickness of the resulting Ga₂O₃ films were studied by ellipsometry after 450 doses of gallium precursor (i.e., triethylgallium or TEG in this instance) for depositing the film under study.

Out-of-plane coupled 1D XRD scans were performed by using a Rigaku Ultima-IV™ diffractometer equipped with a cobalt source, a D/Tex™ ultrahigh-speed position sensitive detector, and a K-β filter at a scan rate of 2°/min and 0.020 steps (which is equivalent to 0.6 s/step exposure). The patterns were converted to copper wavelength for easier comparison with the literature.

Cross-section TEM lamella was prepared by low-energy ion polishing (to minimize damage) using a ThermoFisher Helios Hydra DualBeam™ PFIB (Plasma Focused Ion Beam) system. Atomic resolution STEM analyses (including STEM images and nano-beam diffraction patterns) were performed by using a Thermo Scientific Themis Z S/TEM™ instrument equipped with a high-angle annular dark-field (HAADF) detector.

Results and Discussion.

FIG. 3 shows the XRD results for an ˜22 nm film of metastable α-Ga₂O₃ deposited on c-plane sapphire (α-Al₂O₃) using the GaN-mediated α-Ga₂O₃ deposition method. An intense peak for α-Ga₂O₃ (006) is observed right next to the α-Al₂O₃ (006) peak. No other peaks from α-Ga₂O₃ are present in the pattern which indicates that the α-Ga₂O₃ film is a highly oriented film with α-Ga₂O₃ (006) planes oriented parallel to the surface. Meanwhile, β-Ga₂O₃ peaks are hardly detectable, which is indicative of their low population in the film.

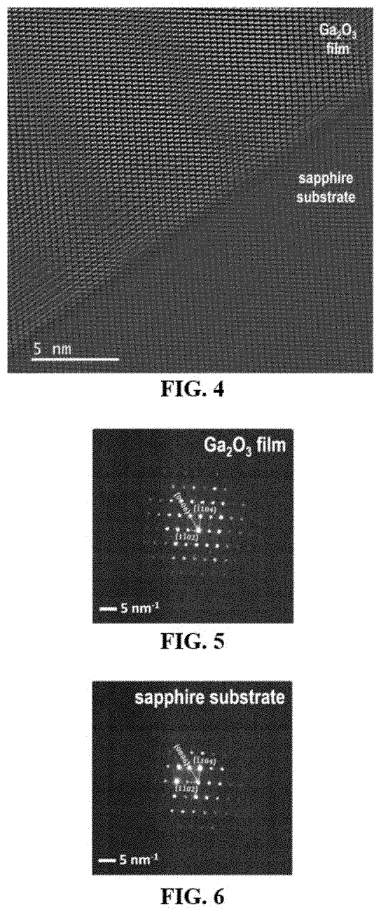

FIGS. 4 to 6 show the transmission electron microscopy (TEM) results for the same ˜22 nm film of metastable α-Ga₂O₃. These figures, particularly the atomic resolution STEM image in FIG. 4, confirm that the entire film (˜22 nm) is crystalline and that the crystal structure is predominantly α-Ga₂O₃ such that α-Ga₂O₃ (006) planes are parallel to the surface. In FIGS. 5 and 6, these results are confirmed from the distinct and intense diffraction spots in the electron diffraction patterns of focused regions of the film and the substrate, respectively.

FIG. 7 shows the out-of-plane XRD scan results for the Ga₂O₃ film deposited directly on the substrate using the conventional Ga₂O₃ deposition process. The Ga₂O₃ film studied in FIG. 7 had a thickness of ˜39.5 nm. From the intense peaks from α-Ga₂O₃ (006) planes as well as β-Ga₂O₃ (2̅01) family of planes parallel to the surface, it is evident that the Ga₂O₃ film is a mixture of α-Ga₂O₃ and β-Ga₂O₃.

FIG. 8 shows the out-of-plane XRD scan results for the Ga₂O₃ film deposited on the buffer layer, in accordance with the buffer-mediated Ga₂O₃ deposition process of the present invention. The Ga₂O₃ film studied in FIG. 8 consists of ˜3 nm layer of α-Ga₂O₃ as the buffer layer, overlaid by an ˜27.5 nm layer of Ga₂O₃ as the bulk of the film. In contrast to the conventional Ga₂O₃ deposition process, the buffer-mediated Ga₂O₃ deposition process produces a substantially single phase β-Ga₂O₃ film. In FIG. 8, three intense peaks from β-Ga₂O₃ (2̅01) family of planes are observed parallel to the surface. More specifically, moving from low to high 2θ angles in FIG. 8, these β-Ga₂O₃ peaks correspond to β-Ga₂O₃ (2̅01), β-Ga₂O₃ (4̅02), and β-Ga₂O₃ (6̅03) planes, respectively. It is worth noting that because the underlying α-Ga₂O₃ buffer layer has been shown to be of high phase purity even when deposited as a thick film (see FIG. 3 and Reference no. 15), the peaks for β-Ga₂O₃ (2̅01) family of planes are attributed to be coming from the bulk of the overlying film (i.e., the ˜27.5 nm topmost layer) and not from the buffer layer. No other peaks from β-Ga₂O₃ are present which indicates that the overlying β-Ga₂O₃ film is a highly oriented film with β-Ga₂O₃ (2̅01) family of planes oriented parallel to the surface. Meanwhile, the weak α-Ga₂O₃ (006) peak observed right next to α-Al₂O₃ (006) peak in FIG. 8, is attributed to the α-Ga₂O₃ (006) planes present in the α-Ga₂O₃ buffer layer, with negligible contributions from α-Ga₂O₃ inclusions in the bulk of the film. The results observed in FIG. 8 indicate that a substantially single phase β-Ga₂O₃ film has been formed as a result of depositing a metastable α-Ga₂O₃ buffer layer prior to depositing Ga₂O₃, in accordance with the buffer-mediated Ga₂O₃ deposition process of the present invention.

Comparing the observed intensity of β-Ga₂O₃ and α-Ga₂O₃ peaks in FIG. 7 and FIG. 8, a dramatic increase in the population of β-Ga₂O₃ planes in the film is apparent as a result of using the buffer-mediated Ga₂O₃ deposition approach of the present invention. It is estimated that the population of β-Ga₂O₃ polymorph in the bulk of the film in FIG. 8 is increased to >>90% (i.e., much more than 90%) (by ratio of mass of β-Ga₂O₃ to mass of α-Ga₂O₃ and β-Ga₂O₃, collectively) as a result of using the buffer-mediated Ga₂O₃ deposition process of the present invention. Analysis of the XRD results indicated that the population of β-Ga₂O₃ polymorph in the bulk of the film was 97.9% by ratio of mass of β-Ga₂O₃ to mass of α-Ga₂O₃ and β-Ga₂O₃, collectively. Thus, in embodiments of the thin film comprising β-Ga₂O₃ formed in accordance with the method of the present invention, the ratio of mass of β-Ga₂O₃ to mass of α-Ga₂O₃ and β-Ga₂O₃, collectively, may be at least 90%, more particularly at least 95%, more particularly at least 97.9%, and more particularly at least 99%. This compares with an almost equal proportion of α-Ga₂O₃ and β-Ga₂O₃ polymorphs in the film produced by the conventional Ga₂O₃ deposition process.

Based on in-situ ellipsometry measurements, after 450 doses of gallium precursor (i.e., triethylgallium or TEG in this instance) for depositing the film under study, the reference α-Ga₂O₃ film deposited by using the GaN-mediated Ga₂O₃ deposition process (FIG. 3) had a thickness of ˜22 nm, the reference α-Ga₂O₃/β-Ga₂O₃ mixed-phase Ga₂O₃ film deposited by using the conventional Ga₂O₃ deposition process (FIG. 7) had a thickness of ˜26 nm, and the β-Ga₂O₃ film deposited by using the buffer-mediated Ga₂O₃ deposition process (FIG. 8) of the present invention had a thickness of ˜27.5 nm. The difference in thickness of the Ga₂O₃ films despite using the same 450 TEG doses (i.e., constant Ga content in the films) is consistent with the fact that β-Ga₂O₃ has a larger molar volume than α-Ga₂O₃ [References no. 9, 10]. Thus, an increase in the amount of β-Ga₂O₃ phase present in the film results in a thicker film for a constant number of TEG doses. Accordingly, with a constant number of TEG doses, the Ga₂O₃ film deposited by using the buffer-mediated Ga₂O₃ deposition process has the largest thickness among all films confirming the largest population of β-Ga₂O₃ in this film.

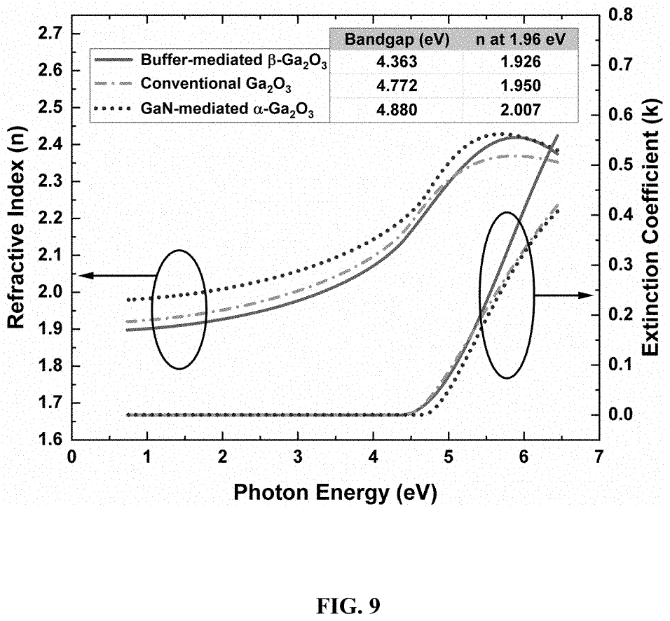

In addition to crystal structure, investigating optical properties of the thin films can provide insights into the quality and performance of the material. To that end, in-situ ellipsometry measurements performed on the aforementioned films (i.e., after the same 450 TEG doses) were also used to study their optical properties. FIG. 9 shows the results of these studies in terms of values of extinction coefficient (k), refractive index (n), and bandgap for the three Ga₂O₃ films.

As shown in FIG. 9, using the GaN-mediated α-Ga₂O₃ deposition process (FIG. 3) results in an α-Ga₂O₃ film with largest refractive index values among the three films over the entire measured spectral range. This observation is consistent with the crystal structure of the films noting that α-Ga₂O₃ has a higher atomic packing density (i.e., smaller molar volume) than β-Ga₂O₃, and thus is expected to have a larger refractive index compared to the R phase [References no. 9, 10].

As shown in FIG. 9, specifically at the photon energy of 1.96 eV (equivalent to 632.8 nm) at which light absorption does not occur in gallium oxide (i.e., k=0 at 632.8 nm), the β-Ga₂O₃ film deposited by using the buffer-mediated Ga₂O₃ deposition process (FIG. 8) has the lowest refractive index value among the three films while the α-Ga₂O₃ film produced by the GaN-mediated α-Ga₂O₃ deposition process (FIG. 3) has the highest refractive index value. Moreover, the α-Ga₂O₃/β-Ga₂O₃ mixed-phase Ga₂O₃ film deposited using the conventional Ga₂O₃ deposition process (FIG. 7) has a refractive index value between the single-phase films. This is consistent with the fact that the conventionally deposited film comprises of a and β-Ga₂O₃ phases.

FIG. 9 also shows that the β-Ga₂O₃ film deposited by using the buffer-mediated Ga₂O₃ deposition process (FIG. 8) has the lowest bandgap value compared to the other films, and the value of bandgap increases as the α-Ga₂O₃ content increases in the film with the GaN-mediated α-Ga₂O₃ film having the highest bandgap value. These observations are consistent with literature reports for bandgap values of a and β-Ga₂O₃ [Reference no. 3] and further confirm the purity of β-Ga₂O₃ phase in the film deposited by using the buffer-mediated Ga₂O₃ deposition approach of the present invention. Based on FIG. 9, the values of extinction coefficient (k) for the Ga₂O₃ films are similar to each other. Meanwhile, compared to the other films, the β-Ga₂O₃ film deposited by using the buffer-mediated Ga₂O₃ deposition process (FIG. 8) has a generally larger extinction coefficient (k) in non-zero regions of the dispersion curves of k which is indicative of a larger concentration of free carriers in the conduction band of the β-Ga₂O₃ film after the free carriers have been excited to the conduction band by photons having high-enough energy [see Reference no. 7 for further explanation].

Without restriction to a theory, the foregoing results—i.e., the high purity of β-Ga₂O₃ phase in the film deposited by using the buffer-mediated Ga₂O₃ deposition approach—may be attributed to the fact that depositing dominantly metastable gallium oxide as an intermediate buffer layer on the substrate before performing the conventional Ga₂O₃ deposition process increases the free energy of the system which makes the formation of β-Ga₂O₃ in the subsequently overlying film more favorable when performing the conventional Ga₂O₃ deposition process on such a high energy underlying template. In other words, limiting the formation of β-Ga₂O₃ domains in the buffer layer by employing suitable strategies and/or restrictions (such as using an atomic scale GaN scaffold in the GaN-mediated Ga₂O₃ deposition strategy for growing high quality α-Ga₂O₃), creates a lot of excess free energy in the system. Therefore, once restrictions are removed and/or process conditions are changed from metastable growth to mixed-phase or conventional growth, the most stable Ga₂O₃ polymorph (i.e., β-Ga₂O₃) will be much more favorable to form (instead of a mixture of β-Ga₂O₃ with other polymorphs) because maximizing the population of β-Ga₂O₃ polymorph in the bulk of the film will lead the system to reach its lowest energy state.

In summary, the present invention provides an epitaxial deposition process that allows for formation of a highly oriented, crystalline β-Ga₂O₃ film on a substrate, which may even be a non-native substrate (and more particularly, a GaN-compatible substrate) at a low thermal budget (i.e., at temperatures that are hundreds of degrees lower than the processes currently in use for β-Ga₂O₃ deposition).

The experimental results demonstrate that this buffer-mediated Ga₂O₃ deposition process (FIG. 8) may minimize the formation of non-β-Ga₂O₃ polymorphs, and hinder formation of a mixed-phase material of β-Ga₂O₃ with other polymorphs, as is produced by the reference conventional Ga₂O₃ deposition process (FIG. 7) at the same deposition temperature and conditions, but which does not involve forming the buffer layer. Accordingly, the crystalline Ga₂O₃ film formed by the present invention may be predominantly of the β-Ga₂O₃ polymorph, with minimal inclusion of other Ga₂O₃ polymorphs.

The present invention makes the development of Ga₂O₃ semiconductor heterostructures and integration of Ga₂O₃ with existing semiconductor device components on a monolithic substrate possible and facilitates fast-track development of Ga₂O₃ electronics. Development of a low temperature technology for β-Ga₂O₃ growth (specially a GaN-compatible one) as a result of the present invention is a key enabling technology for wide bandgap semiconductors leading to energy-efficient electronic devices, not only in performance but also an energy-efficient fabrication process. Fabrication of Ga₂O₃ devices on non-native substrates using the present invention also allows for the transfer of pertinent thermal management technologies that are already established for wide bandgap electronics [Reference no. 16], which will mitigate the low thermal conductivity of Ga₂O₃ and make devices available that are able to concurrently handle higher power, higher voltage, and higher operating temperatures.

Interpretation.

The corresponding structures, materials, acts, and equivalents of all means or steps plus function elements in the claims appended to this specification are intended to include any structure, material, or act for performing the function in combination with other claimed elements as specifically claimed.

References in the specification to “one embodiment”, “an embodiment”, etc., indicate that the embodiment described may include a particular aspect, feature, structure, or characteristic, but not every embodiment necessarily includes that aspect, feature, structure, or characteristic. Moreover, such phrases may, but do not necessarily, refer to the same embodiment referred to in other portions of the specification. Further, when a particular aspect, feature, structure, or characteristic is described in connection with an embodiment, it is within the knowledge of one skilled in the art to affect or connect such module, aspect, feature, structure, or characteristic with other embodiments, whether or not explicitly described. In other words, any module, element or feature may be combined with any other element or feature in different embodiments, unless there is an obvious or inherent incompatibility, or it is specifically excluded.

It is further noted that the claims may be drafted to exclude any optional element. As such, this statement is intended to serve as antecedent basis for the use of exclusive terminology, such as “solely,” “only,” and the like, in connection with the recitation of claim elements or use of a “negative” limitation. The terms “preferably,” “preferred,” “prefer,” “optionally,” “may,” and similar terms are used to indicate that an item, condition or step being referred to is an optional (not required) feature of the invention.

The singular forms “a,” “an,” and “the” include the plural reference unless the context clearly dictates otherwise. The term “and/or” means any one of the items, any combination of the items, or all of the items with which this term is associated. The phrase “one or more” is readily understood by one of skill in the art, particularly when read in context of its usage.

The term “about” or “˜” can refer to a variation of ±5%, ±10%, ±20%, or ±25% of the value specified. For example, “about 50” percent can in some embodiments carry a variation from 45 to 55 percent. For integer ranges, the term “about” or “˜” can include one or two integers greater than and/or less than a recited integer at each end of the range. Unless indicated otherwise herein, the term “about” or “˜” is intended to include values and ranges proximate to the recited range that are equivalent in terms of the functionality of the composition, or the embodiment.

As will be understood by one skilled in the art, for any and all purposes, particularly in terms of providing a written description, all ranges recited herein also encompass any and all possible sub-ranges and combinations of sub-ranges thereof, as well as the individual values making up the range, particularly integer values. A recited range includes each specific value, integer, decimal, or identity within the range. Any listed range can be easily recognized as sufficiently describing and enabling the same range being broken down into at least equal halves, thirds, quarters, fifths, or tenths. As a non-limiting example, each range discussed herein can be readily broken down into a lower third, middle third and upper third, etc.

As will also be understood by one skilled in the art, all language such as “up to”, “at least”, “greater than”, “less than”, “more than”, “or more”, and the like, include the number recited and such terms refer to ranges that can be subsequently broken down into sub-ranges as discussed above. In the same manner, all ratios recited herein also include all sub-ratios falling within the broader ratio.

### REFERENCES

The following publications cited herein are indicative of the level of one skilled in the art and are incorporated herein by reference in their entireties, except for any subject matter disclaimers or disavowals, and except to the extent that the incorporated material is inconsistent with the express disclosure herein, in which case the language in this disclosure controls.
1. Mastro, M. A.; Kuramata, A.; Calkins, J.; Kim, J.; Ren, F.; Pearton, S. J. Perspective-Opportunities and Future Directions for Ga2O3. ECS J. Solid State Sci. Technol. 2017, 6, P356-P359.
2. Higashiwaki, M.; Sasaki, K.; Kuramata, A.; Masui, T.; Yamakoshi, S. Development of Gallium Oxide Power Devices. Phys. Status Solidi A 2014, 211, 21-26.
3. Pearton, S. J.; Yang, J.; Cary, P. H.; Ren, F.; Kim, J.; Tadjer, M. J.; Mastro, M. A. A Review of Ga2O3 Materials, Processing, and Devices. Appl. Phys. Rev. 2018, 5, 011301.
4. Pearton, S. J.; Ren, F.; Tadjer, M.; Kim, J. Perspective: Ga2O3 for Ultra-High Power Rectifiers and MOSFETS. J. Appl. Phys. 2018, 124, 220901.
5. Higashiwaki, M.; Jessen, G. H. Guest Editorial: The Dawn of Gallium Oxide Microelectronics. Appl. Phys. Lett. 2018, 112, 060401.
6. Ahmadi, E.; Oshima, Y. Materials Issues and Devices of α- and β-Ga2O3. J. Appl. Phys. 2019, 126, 160901.
7. Rafie Borujeny, E.; Sendetskyi, O.; Fleischauer, M. D.; Cadien, K. C. Low Thermal Budget Heteroepitaxial Gallium Oxide Thin Films Enabled by Atomic Layer Deposition. ACS Appl. Mater. Interfaces 2020, 12, 44225-44237.
8. Wheeler, V. D.; Nepal, N.; Boris, D. R.; Qadri, S. B.; Nyakiti, L. O.; Lang, A.; Koehler, A.; Foster, G.; Walton, S. G.; Eddy, C. R.; Meyer, D. J. Phase Control of Crystalline Ga2O3 Films by Plasma-Enhanced Atomic Layer Deposition. Chem. Mater. 2020, 32, 1140-1152.
9. He, H.; Orlando, R.; Blanco, M. A.; Pandey, R.; Amzallag, E.; Baraille, I.; Rérat, M. First-Principles Study of the Structural, Electronic, and Optical Properties of Ga2O3 in its Monoclinic and Hexagonal Phases. Phys. Rev. B 2006, 74, 195123.
10. Zinkevich, M.; Aldinger, F. Thermodynamic Assessment of the Gallium-Oxygen System. J. Am. Ceram. Soc. 2004, 87, 683-691.
11. Playford, H. Y.; Hannon, A. C.; Barney, E. R.; Walton, R. I. Structures of Uncharacterised Polymorphs of Gallium Oxide from Total Neutron Diffraction. Chem.-Eur. J. 2013, 19, 2803-2813.
12. Cora, I.; Mezzadri, F.; Boschi, F.; Bosi, M.; C\check{a}plovičová, M.; Calestani, G.; Dódony, I.; Pécz, B.; Fornari, R. The Real Structure of ε-Ga2O3 and its Relation to κ-Phase. Cryst Eng Comm 2017, 19, 1509-1516.
13. Roy, R.; Hill, V. G.; Osborn, E. F. Polymorphs of Alumina and Gallia. Ind. Eng. Chem. 1953, 45, 819-820.
14. Yoshioka, S.; Hayashi, H.; Kuwabara, A.; Oba, F.; Matsunaga, K.; Tanaka, I. Structures and Energetics of Ga2O3 Polymorphs. J. Phys.: Condens. Matter 2007, 19, 346211.
15. Rafie Borujeny, E.; Cadien, K. Deposition of Alpha-Gallium Oxide Thin Films. U.S. Patent Application No. 63/137,874, filed Jan. 15, 2021.
16. Guggenheim, R.; Rodes, L. Roadmap Review for Cooling High-Power GaN HEMT Devices. 2017 IEEE International Conference on Microwaves, Antennas, Communications and Electronic Systems (COMCAS) 2017, 1-6.
17. Motamedi, P.; Dalili, N.; Cadien, K. A Route to Low Temperature Growth of Single Crystal GaN on Sapphire. J. Mater. Chem. C 2015, 3, 7428-7436.
18. Motamedi, P.; Cadien, K. Structure-Property Relationship and Interfacial Phenomena in GaN Grown on C-Plane Sapphire via Plasma-Enhanced Atomic Layer Deposition. RSC Adv. 2015, 5, 57865-57874.
19. Afshar, A. Materials Characterization and Growth Mechanisms of ZnO, ZrO2, and HfO2 Deposited by Atomic Layer Deposition, University of Alberta, PhD Thesis, 2014.

1. A method for forming a thin film comprising beta-gallium oxide (β-Ga₂O₃) on a substrate, the method using an epitaxial deposition process comprising the steps of:
(a) depositing a buffer layer of metastable Ga₂O₃ on the substrate; and
(b) reacting a gallium precursor with an oxygen precursor to deposit a layer comprising β-Ga₂O₃ on the buffer layer.

2. The method of claim 1, further comprising repeating step (b) of claim 1 to deposit one or more additional layers comprising β-Ga₂O₃ on a previously deposited layer comprising β-Ga₂O₃.

3. The method of claim 1, wherein the layer comprising β-Ga₂O₃ comprises at least 90% β-Ga₂O₃, by ratio of mass of β-Ga₂O₃ to mass of α-Ga₂O₃ and β-Ga₂O₃, collectively.

4. The method of claim 1, wherein the epitaxial deposition process is an atomic layer deposition (ALD) process.

5. The method of claim 1, wherein the buffer layer is a single monolayer of metastable Ga₂O₃.

6. The method of claim 1, wherein the layer comprising β-Ga₂O₃ is a single monolayer comprising β-Ga₂O₃.

7. The method of claim 1, wherein the gallium precursor comprises triethylgallium (TEG) gas.

8. The method of claim 1, wherein the oxygen precursor comprises an oxygen plasma.

9. The method of claim 1, wherein step (b) of claim 1 comprises the sub-steps of:
(i) providing a 0.1 s pulsed dose of the gallium precursor comprising triethylgallium (TEG) into a reaction chamber containing the substrate; and
(ii) providing a 10 s pulsed dose of the oxygen precursor comprising oxygen plasma into the reaction chamber.

10. The method of claim 1, wherein the metastable gallium oxide comprises α-Ga₂O₃.

11. The method of claim 10, wherein step (a) of claim 1 comprises the sub-steps of:
(i) depositing a layer of wurtzite gallium nitride (w-GaN) on the substrate; and
(ii) reacting the layer of w-GaN with an oxygen precursor to deposit the buffer layer comprising α-Ga₂O₃ on the substrate.

12. The method of claim 11, wherein sub-step (i) of claim 11 comprises the sub-steps of:
(1) depositing a layer of gallium precursor on the substrate; and
(2) reacting the layer of gallium precursor with a nitrogen precursor to deposit the layer of w-GaN on the substrate.

13. The method of claim 12, wherein the gallium precursor used in sub-step (1) of claim 12 comprises triethylgallium (TEG) gas.

14. The method of claim 12, wherein the nitrogen precursor used in sub-step (2) of claim 12 comprises N₂/H₂ forming gas plasma.

15. The method of claim 11, wherein the oxygen precursor used in sub-step (ii) comprises oxygen plasma.

16. The method of claim 12, wherein
sub-step (1) of claim 12 comprises providing a 0.1 s pulsed dose of the gallium precursor comprising triethylgallium (TEG) into a reaction chamber containing the substrate;
sub-step (2) of claim 12 comprises providing a 15 s pulsed dose of the nitrogen precursor comprising N₂/H₂ forming gas plasma into the reaction chamber; and
sub-step (ii) of claim 11 comprises providing a 1.5 s pulsed dose of the oxygen precursor comprising oxygen plasma into the reaction chamber.

17. The method of claim 1, wherein the substrate is a non-native substrate.

18. The method of claim 17, wherein the non-native substrate comprises a sapphire.

19. The method of claim 18, wherein the sapphire is c-plane sapphire.

20. A thin film comprising beta-gallium oxide (β-Ga₂O₃) formed on a non-native substrate by the method of claim 1.
